(19) United States
(12) Patent Application Publication
(10) Pub. No.: US 2019/0305228 A1
(43) Pub. Date: Oct. 3, 2019

(54) ORGANIC LIGHTEMITTING COMPOUND HAVING PHOSPHORESCENT CHARACTERISTIC AT ROOM TEMPERATURE, AND PHOSPHORESCENT ORGANIC LIGHT EMITTING DEVICE INCLUDING THE ORGANIC LIGHTEMITTING COMPOUND

(71) Applicant: Research & Business Foundation Sungkyunkwan University, Suwon-si (KR)

(72) Inventors: Jun Yeob LEE, Seongnam-si (KR); Dong Ryun LEE, Seongnam-si (KR)

(73) Assignee: Research & Business Foundation Sungkyunkwan Univer sity, Suwon-si (KR)

(21) Appl. No.: 16/367,617

(22) Filed: Mar. 28, 2019

(30) Foreign Application Priority Data
Mar. 28, 2018 (KR) 10-2018-0035863

(51) Int. Cl. H01L 51/00; H01L 51/50; C07F 11/00

(52) U.S. Cl. CPC H01L 51/0072; H01L 51/0067; C07F 11/00; H01L 51/5016; H01L 51/0061

(57) ABSTRACT

Disclosed is an organic light-emitting compound having a phosphorescent characteristic at room temperature and a phosphorescent organic light-emitting device containing the same. The organic light-emitting compound includes a compound represented by a following Chemical Formula 1:

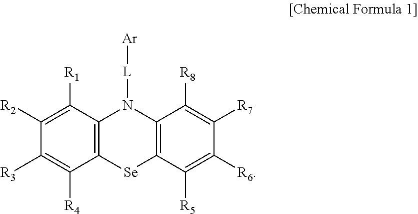

### CROSS-REFERENCE TO RELATED APPLICATION

This application claims a benefit under 35 U.S.C. § 119(a) of Korean Patent Application No. 10-2018-0035863 filed on Mar. 28, 2018, in the Korean Intellectual Property Office, the entire disclosure of which is incorporated herein by reference for all purposes.

### BACKGROUND

### 1. Field

The present disclosure relates to an organic light-emitting compound having a phosphorescent characteristic at room temperature and a phosphorescent organic light-emitting device containing the same. More particularly, the present disclosure relates to an organic light-emitting compound having a phosphorescent characteristic at room temperature without employing a transition metal and a phosphorescent organic light-emitting device containing the same.

### 2. Description of Related Art

An organic electroluminescent device is an electronic device having advantages of low power consumption and long lifetime, and is widely used for medium/small sized displays, illumination devices, and the like.

In an exciton formation process in the organic electroluminescent device, singlet excitons and triplet excitons are formed at a ratio of 1:3 based on quantum spin statistics. However, since a typical organic luminescent molecule cannot use the triplet excitons for luminescence due to spin selectivity of electron transition, the typical organic luminescent molecule has a limited internal quantum efficiency of 25% regarding fluorescent luminescence.

A phosphorescence emitting molecule including a transition metal such as iridium or platinum having a high atomic number has been proposed by improving luminous efficiency of the organic luminescent molecule. Since organometallic phosphorescent compounds, which are combinations of such transition metals and organic luminous molecules, employ expensive transition metals, the organometallic phosphorescent compounds have a high production cost. Further, in the organometallic phosphorescent compounds, due to the weak bond strength between the transition metal atom and the organic ligand, the organometallic phosphorescent compounds have the disadvantage of having an unstable molecular structure.

Therefore, there is a demand for development of new molecules for removing the disadvantages of the organometallic phosphorescence emitting molecules including the transition metals. In addition, room temperature-based organic phosphorescent materials, which do not employ the previously developed transition metals, exhibit phosphorescent characteristics only in a crystalline state or in a state in which dopants are doped into a polymer. Thus, such a materials may not be applied to an organic electroluminescent device. Further, these materials contain halogen atoms, such as bromine, that cause a device lifespan to be shortened. Further, it is currently reported that a maximum quantum efficiency of a room temperature-based phosphorescent organic electroluminescent device using organic materials is very low.

### SUMMARY

This Summary is provided to introduce a selection of concepts in a simplified form that are further described below in the Detailed Description. This Summary is not intended to identify all key features or essential features of the claimed subject matter, nor is it intended to be used alone as an aid in determining the scope of the claimed subject matter.

One purpose of the present disclosure is to provide an organic light-emitting compound having an improved phosphorescent characteristic at room temperature, in which the limited internal quantum efficiency of organic light emitting molecules is improved and the compound is free of the transition metal in order to remove the disadvantages of the organometallic phosphorescent compounds containing the conventional expensive and unstable transition metals.

Another purpose of the present disclosure is to provide a phosphorescent organic light-emitting device containing the organic light-emitting compound with the improved phosphorescent characteristics at room temperature.

An organic light-emitting compound with a phosphorescent characteristic at room temperature for said one purpose of the present disclosure includes a compound represented by a following Chemical Formula 1:

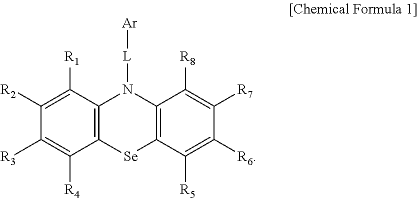

wherein, Ar represents an electron-donor unit or an electron-acceptor unit,

wherein L represents —(C₆H₄)ₙ-(n is a natural number of 0 or 1 or greater),

wherein each of R₁ to R₈ independently represents a halogen atom, hydrogen, deuterium, an alkyl group having 1 to 60 carbon atoms, an alkenyl group having 2 to 60 carbon atoms, an alkynyl group having 2 to 60 carbon atoms, an aryl group having 6 to 60 carbon atoms, a heteroaryl group having 3 to 60 carbon atoms, an alkoxy group having 1 to 60 carbon atoms, an aryloxy group having 6 to 60 carbon atoms, an arylalkyl group having 7 to 60 carbon atoms, a heteroarylalkyl group having 3 to 60 carbon atoms, a cycloalkyl group having 3 to 60 carbon atoms, a heterocycloalkyl group having 1 to 60 carbon atoms, an alkylsilyl group having 3 to 60 carbon atoms, an arylsilyl group having 3 to 60 carbon atoms, or a heteroarylsilyl group having 1 to 60 carbon atoms,

wherein in each of L (where n is a natural number equal to or greater than 1) and Ar, each of at least one hydrogen is independently substitutable with a halogen element, an alkyl group having 1 to 60 carbon atoms, an alkenyl group having 2 to 60 carbon atoms, an alkynyl group having 2 to 60 carbon atoms, an aryl group having 6 to 60 carbon atoms, a heteroaryl group having 3 to 60 carbon atoms, an alkoxy group having 1 to 60 carbon atoms, an aryloxy group having 6 to 60 carbon atoms, an arylalkyl group having 7 to 60 carbon atoms, a heteroarylalkyl group having 3 to 60 carbon atoms, a cycloalkyl group having 3 to 60 carbon atoms, a heterocycloalkyl group having 1 to 60 carbon atoms, an alkylsilyl group having 3 to 60 carbon atoms, an arylsilyl group having 3 to 60 carbon atoms or a heteroarylsilyl group having 1 to 60 carbon atoms.

A phosphorescent organic light-emitting device for said another purpose of the present disclosure comprises an anode, a cathode, a phosphorescent light emission layer disposed therebetween. The phosphorescent light emission layer contains a host compound and an organic light-emitting compound represented by the Chemical Formula 1 as a dopant.

According to the organic light-emitting compound having the phosphorescent characteristic at the room temperature and the phosphorescent organic light-emitting device containing the same in accordance with the present disclosure, developing the organic light-emitting compound with a phosphorescent characteristic at room temperature without containing a transition metal may allow triplet excitons to be used for luminescence, which otherwise may not be used and may be extinguished for luminescence in the conventional organic light-emitting compounds. As a result, the limited quantum efficiency of the organic light-emitting compound is improved. Further, the increase in the production cost and the instability of the molecular structure due to the introduction of the transition metal into the existing organometallic phosphorescent light emitting molecule may be eliminated.

### DETAILED DESCRIPTIONS

Examples of various embodiments are illustrated and described further below. It will be understood that the description herein is not intended to limit the claims to the specific embodiments described. On the contrary, it is intended to cover alternatives, modifications, and equivalents as may be included within the spirit and scope of the present disclosure as defined by the appended claims.

The descriptions and details of well-known steps and elements are omitted for simplicity of the description. Furthermore, in the following detailed description of the present disclosure, numerous specific details are set forth in order to provide a thorough understanding of the present disclosure. However, it will be understood that the present disclosure may be practiced without these specific details.

The terminology used herein is for the purpose of describing particular embodiments only and is not intended to be limiting of the present disclosure. As used herein, the singular forms “a” and “an” are intended to include the plural forms as well, unless the context clearly indicates otherwise. It will be further understood that the terms “comprises”, “comprising”, “includes”, and “including” when used in this specification, specify the presence of the stated features, integers, operations, elements, and/or components, but do not preclude the presence or addition of one or more other features, integers, operations, elements, components, and/or portions thereof. As used herein, the term “and/or” includes any and all combinations of one or more of the associated listed items. Expression such as “at least one of” when preceding a list of elements may modify the entire list of elements and may not modify the individual elements of the list.

In addition, it will also be understood that when a first element or layer is referred to as being present “on” a second element or layer, the first element may be disposed directly on the second element or may be disposed indirectly on the second element with a third element or layer being disposed between the first and second elements or layers. It will be understood that when an element or layer is referred to as being “connected to”, or “coupled to” another element or layer, it can be directly on, connected to, or coupled to the other element or layer, or one or more intervening elements or layers may be present. In addition, it will also be understood that when an element or layer is referred to as being “between” two elements or layers, it can be the only element or layer between the two elements or layers, or one or more intervening elements or layers may also be present.

Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

An organic light-emitting compound with a phosphorescent characteristic at room temperature according to the present disclosure has a phenoselenazine structure containing a selenium atom (Se) having a difference of an atomic number 1 from that of a bromine atom (Br) conventionally used for improving the phosphorescent characteristic at room temperature via the heavy atom effect. This phenoselenazine structure can maximize the spin orbit coupling effect via the heavy atom effect. Thus, the inter-system transition from singlet excitons to triplet excitons can be activated. Thus, the organic compound according to the present disclosure realizes phosphorescent emission corresponding to prohibited transition due to increased spin orbit coupling.

The organic light-emitting compound with the phosphorescent characteristic at room temperature according to the present disclosure is expressed by the following Chemical Formula 1:

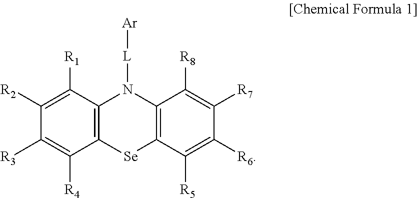

wherein, Ar represents an electron-donor unit or an electron-acceptor unit,

wherein L represents —(C₆H₄)ₙ-(n is a natural number of 0 or 1 or greater),

wherein each of R₁ to R₈ independently represents a halogen atom, hydrogen, deuterium, an alkyl group having 1 to 60 carbon atoms, an alkenyl group having 2 to 60 carbon atoms, an alkynyl group having 2 to 60 carbon atoms, an aryl group having 6 to 60 carbon atoms, a heteroaryl group having 3 to 60 carbon atoms, an alkoxy group having 1 to 60 carbon atoms, an aryloxy group having 6 to 60 carbon atoms, an arylalkyl group having 7 to 60 carbon atoms, a heteroarylalkyl group having 3 to 60 carbon atoms, a cycloalkyl group having 3 to 60 carbon atoms, a heterocycloalkyl group having 1 to 60 carbon atoms, an alkylsilyl group having 3 to 60 carbon atoms, an arylsilyl group having 3 to 60 carbon atoms, or a heteroarylsilyl group having 1 to 60 carbon atoms,

wherein in each of L (where n is a natural number equal to or greater than 1) and Ar, each of at least one hydrogen is independently substitutable with a halogen element, an alkyl group having 1 to 60 carbon atoms, an alkenyl group having 2 to 60 carbon atoms, an alkynyl group having 2 to 60 carbon atoms, an aryl group having 6 to 60 carbon atoms, a heteroaryl group having 3 to 60 carbon atoms, an alkoxy group having 1 to 60 carbon atoms, an aryloxy group having 6 to 60 carbon atoms, an arylalkyl group having 7 to 60 carbon atoms, a heteroarylalkyl group having 3 to 60 carbon atoms, a cycloalkyl group having 3 to 60 carbon atoms, a heterocycloalkyl group having 1 to 60 carbon atoms, an alkylsilyl group having 3 to 60 carbon atoms, an arylsilyl group having 3 to 60 carbon atoms or a heteroarylsilyl group having 1 to 60 carbon atoms.

In the Chemical Formula 1, when n in L represents 0, this means a single bond. When L represents the single bond, N and Ar are directly connected to each other.

In the Chemical Formula 1, the electron-donor unit may be a functional group derived from compounds represented by following Chemical Formulas (1-1) to (1-36). In this connection, the term “functional group derived from the compound” means a functional group obtained by removing one hydrogen atom from the corresponding compound and binding L in the Chemical Formula 1 to the corresponding compound. In this connection, the binding position is not particularly limited.

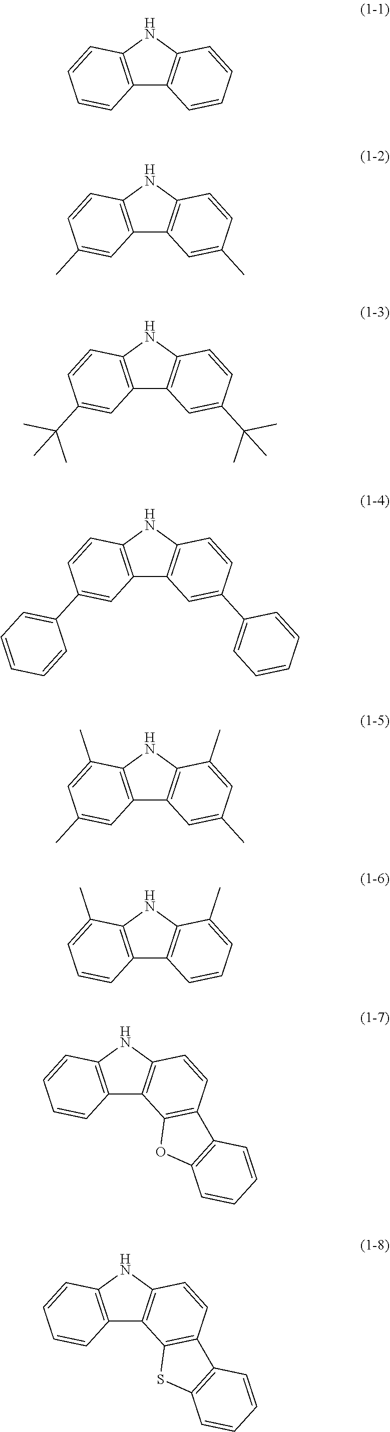

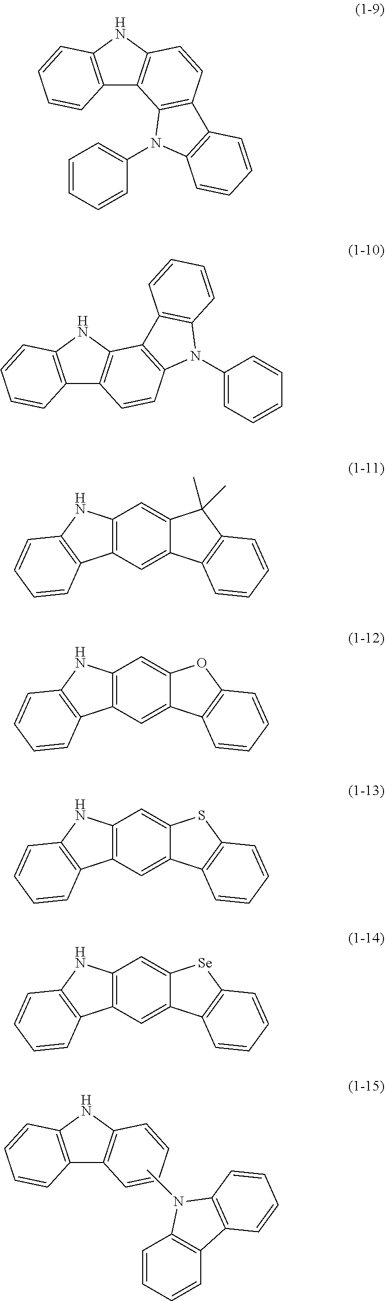

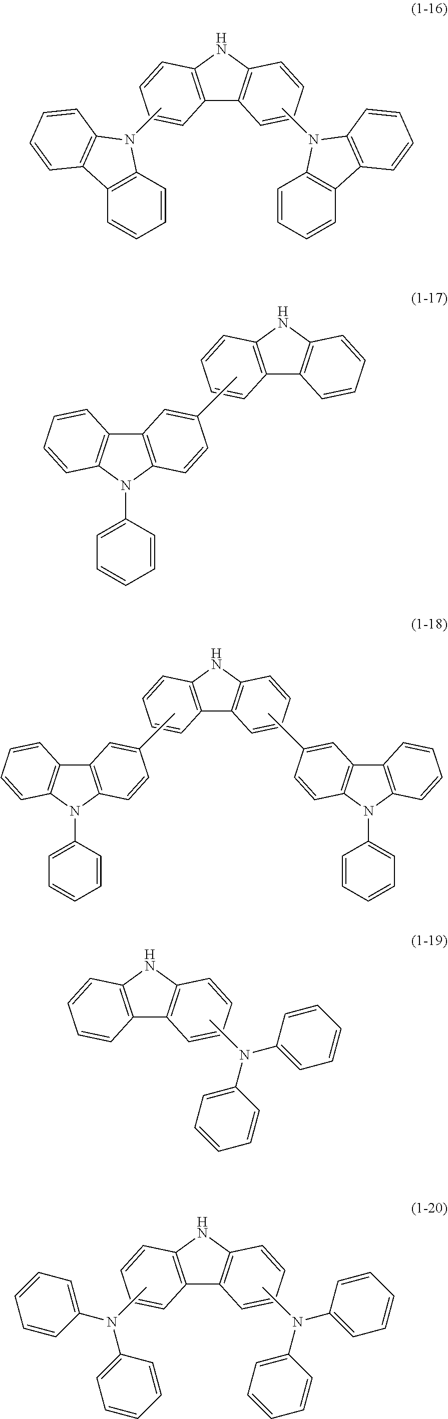

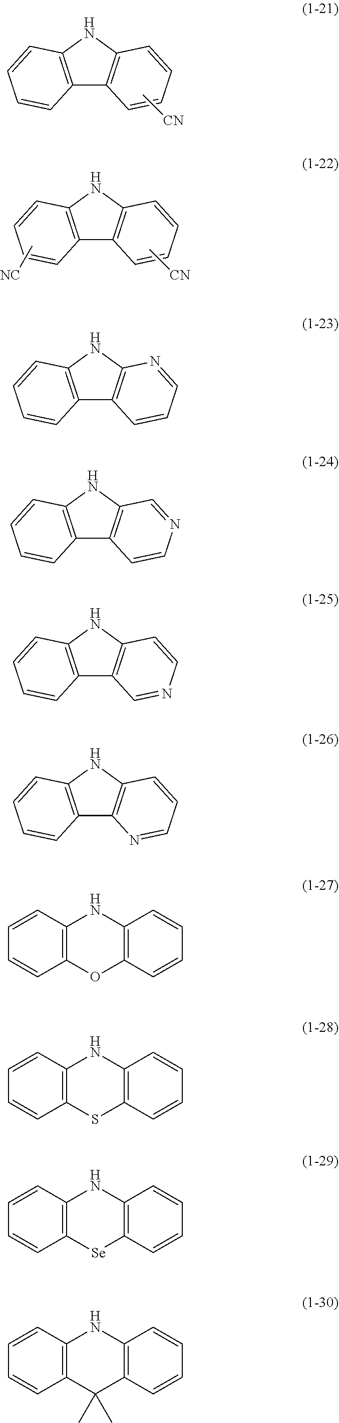

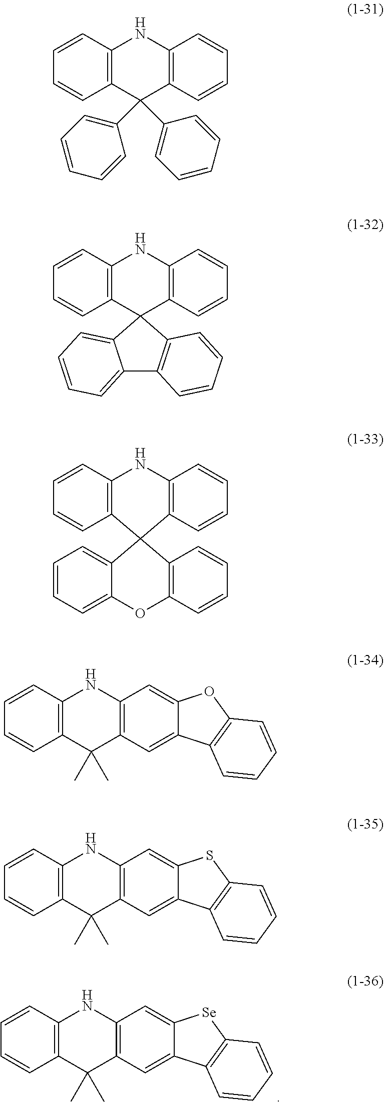

In the Chemical Formula 1, the electron-acceptor unit may be a functional group represented by following Chemical Formulas (2-1) to (2-13). In this connection, in each of the following Chemical Formula (2-1) to (2-13), “*” denotes a position where L in the Chemical Formula 1 binds to the corresponding functional group:

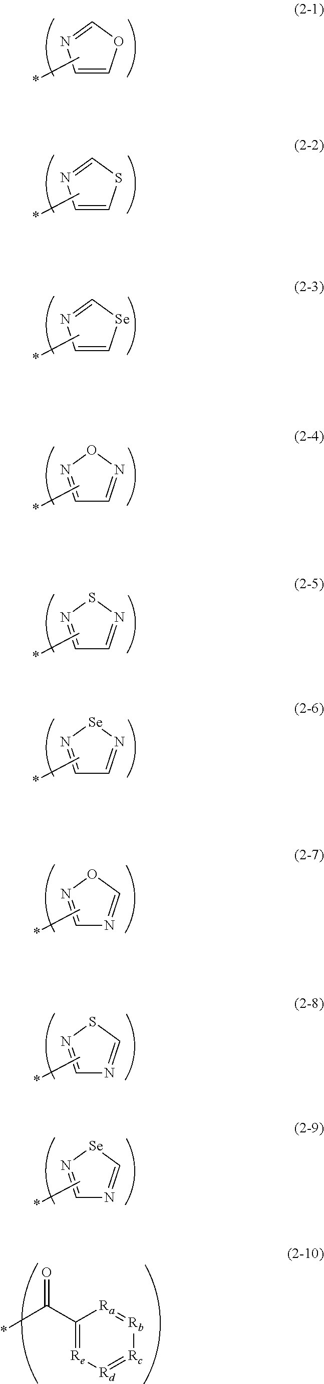

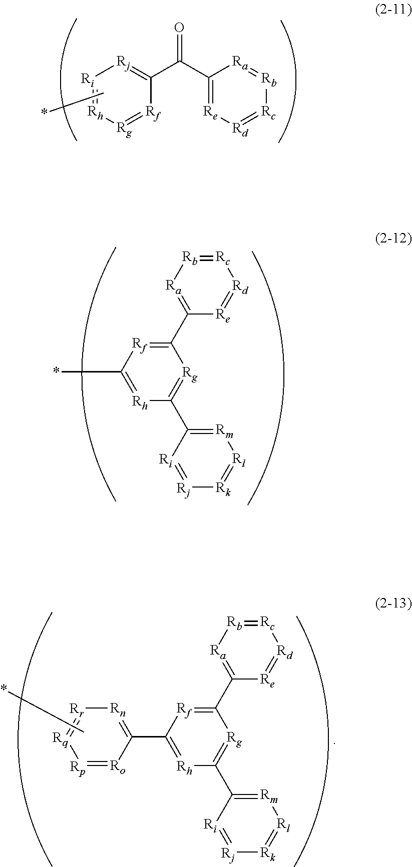

In this connection, each of Rₐ to Rₑ of Chemical Formula (2-10), each of Rₐ to Rⱼ of Chemical Formula (2-11), each of Rₐ to Rₘ of Chemical Formula (2-12), and each of Rₐ to Rᵣ of Chemical Formula (2-13) independently represents C, S, O, N or Se.

In one embodiment, a specific example of the compounds represented by the Chemical Formula 1 may include a compound represented by a following Chemical Formula 3-1:

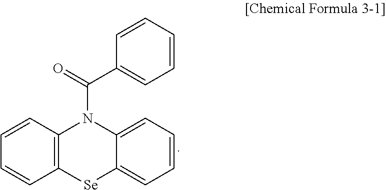 [SMILES: O=C(c1ccccc1)N1c2ccccc2[Se]c2ccccc21]

In one embodiment, the compound represented by the Chemical Formula 1 may include a compound represented by a following Chemical Formula 3-2 or a following Chemical Formula 3-3:

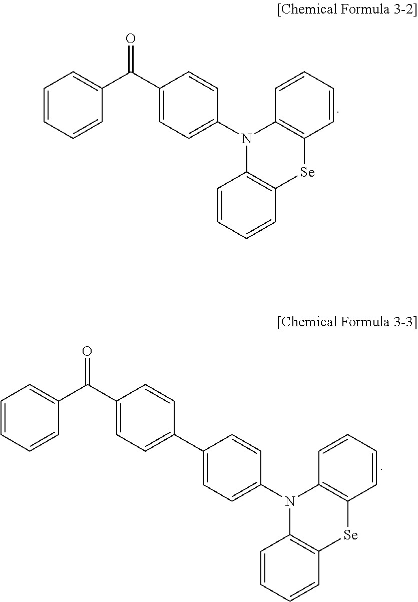 [SMILES: O=C(c1ccccc1)c1ccc(N2c3ccccc3[Se]c3ccccc32)cc1 ; O=C(c1ccccc1)c1ccc(-c2ccc(N3c4ccccc4[Se]c4ccccc43)cc2)cc1]

In one embodiment, the compound represented by the Chemical Formula 1 may include any one of compounds represented by following Chemical Formulas 3-4 to 3-7:

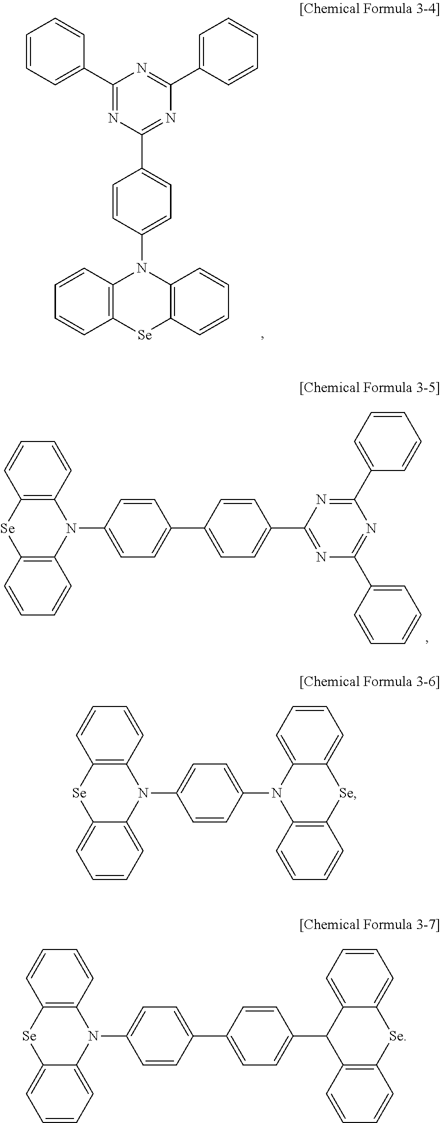

The phenoselenazine as a skeleton of a compound represented by the Chemical Formula 1 according to the present disclosure may be synthesized according to a following Reaction Formula 1:

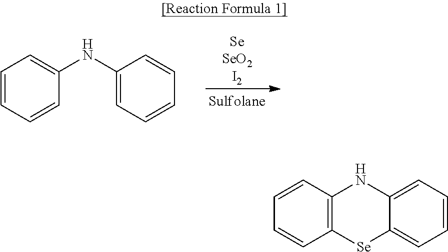 [SMILES: c1ccc(Nc2ccccc2)cc1 ; c1ccc2c(c1)Nc1ccccc1[Se]2]

In one embodiment, a compound containing a carbonyl group represented by the Chemical Formula 3-1 and the phenoselenazine may be synthesized according to a following Reaction Formula 2:

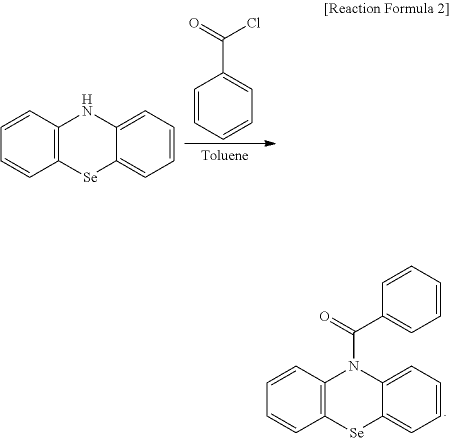

In one embodiment, a compound containing a carbonyl group represented by the Chemical Formula 3-2 and the phenoselenazine may be synthesized according to a following Reaction Formula 3:

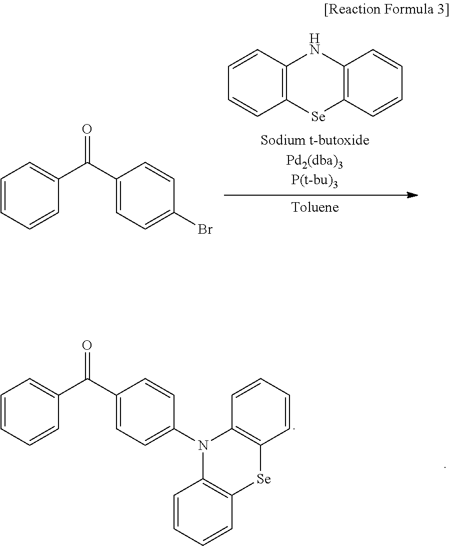 [SMILES: c1ccc2c(c1)Nc1ccccc1[Se]2 ; O=C(c1ccccc1)c1ccc(Br)cc1 ; O=C(c1ccccc1)c1ccc(N2c3ccccc3[Se]c3ccccc32)cc1]

In one embodiment, a compound containing a carbonyl group represented by the Chemical Formula 3-3 and the phenoselenazine may be synthesized according to a following Reaction Formula 4:

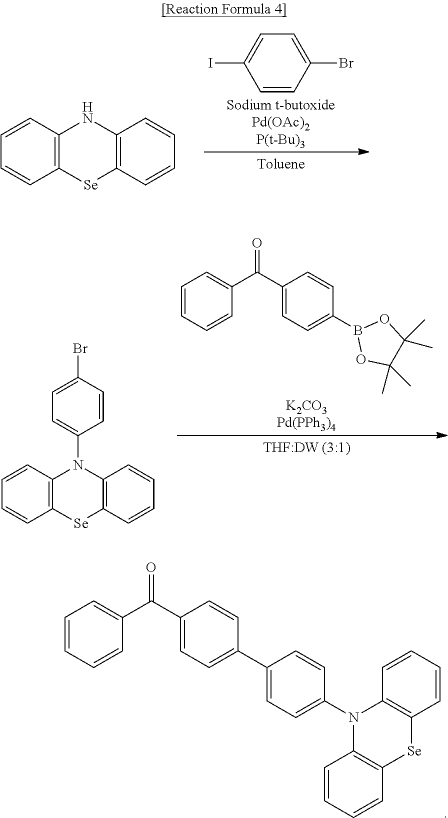 [SMILES: Brc1ccc(I)cc1 ; c1ccc2c(c1)Nc1ccccc1[Se]2 ; Brc1ccc(N2c3ccccc3[Se]c3ccccc32)cc1 ; CC1(C)OB(c2ccc(C(=O)c3ccccc3)cc2)OC1(C)C ; O=C(c1ccccc1)c1ccc(-c2ccc(N3c4ccccc4[Se]c4ccccc43)cc2)cc1 ; "."]

In one embodiment, a compound containing a triazine represented by the Chemical Formula 3-4 and the phenoselenazine may be synthesized according to a following Reaction Formula 5:

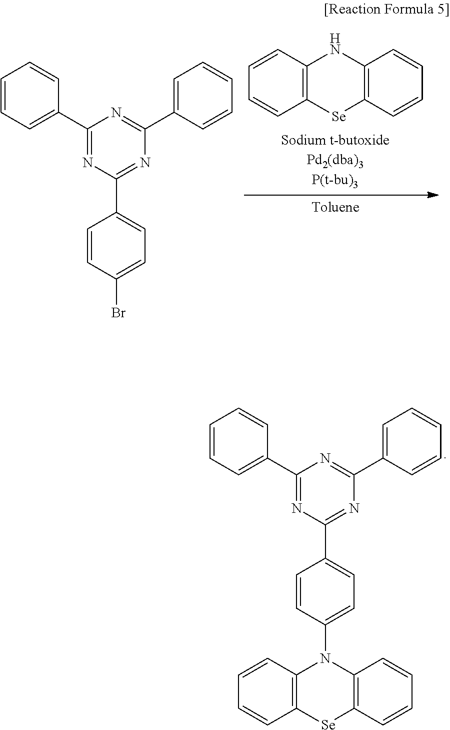

In one embodiment, a compound containing a triazine represented by the Chemical Formula 3-5 and the phenoselenazine may be synthesized according to a following Reaction Formula 6:

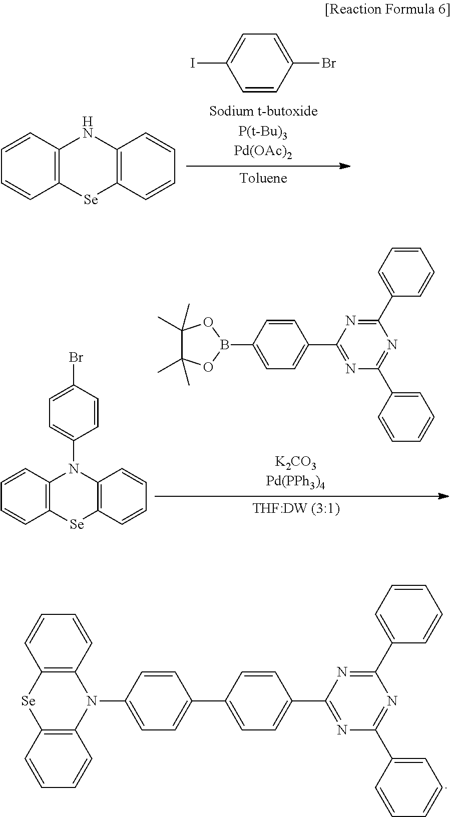 [SMILES: Brc1ccc(I)cc1 ; c1ccc2c(c1)Nc1ccccc1[Se]2 ; Brc1ccc(N2c3ccccc3[Se]c3ccccc32)cc1 ; CC1(C)OB(c2ccc(-c3nc(-c4ccccc4)nc(-c4ccccc4)n3)cc2)OC1(C)C ; c1ccc(-c2nc(-c3ccccc3)nc(-c3ccc(-c4ccc(N5c6ccccc6[Se]c6ccccc65)cc4)cc3)n2)cc1]

In one embodiment, a compound containing two phenoselenazines, each represented by the Chemical Formula 3-6, may be synthesized according to a following Reaction Formula 7:

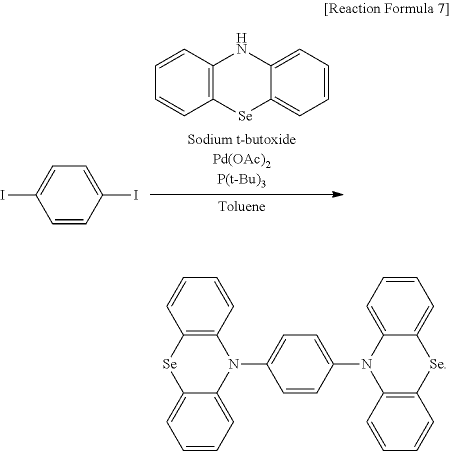

In one embodiment, a compound containing two phenoselenazines, each represented by the Chemical Formula 3-7, may be synthesized according to a following Reaction Formula 8:

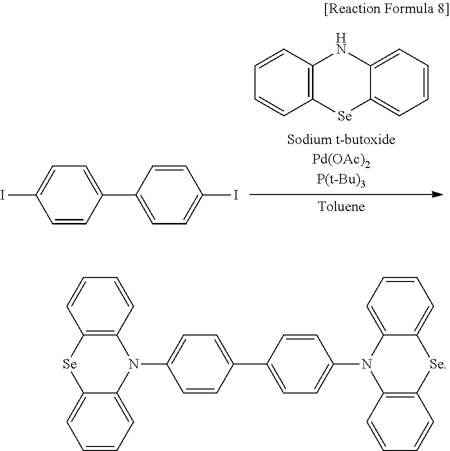

An organic light-emitting compound having a phosphorescent characteristic at room temperature according to the present disclosure is mixed with a host material to define a layer together with the host material, the layer constituting a phosphorescent organic light-emitting device.

In this connection, the host material may be contained at 50 to 99% by volume, assuming that a total volume of the layer is 100%. When the organic light-emitting compound according to the present disclosure is contained in an amount of smaller than 1% by volume, the energy transfer effect may be weak and the efficiency may be too low. When the content of the organic light-emitting compound according to the present disclosure exceeds 50% by volume, the efficiency may be lowered due to crystallization of the dopant material.

Examples of the host material may include 4,7-diphenyl-1,10-phenanthroline (Bphen), 2,2′,2″-(benzene-1,3,5-triyl)-tris(1-phenyl-1Hbenzimidazole) (TPBI), 2,9-dimethyl-4,7-diphenyl-1,10-phenanthroline (BCP), Bis(2-methyl-8-quinolinolate)-4-(phenylphenolato)aluminium (Balq), 1,3-bis[2-(2,2′-bipyridine-6-yl)-1,3,4-oxadiazo-5-yl]benzene (Bpy-OXD), 6,6′-bis[5-(biphenyl-4-yl)-1,3,4-oxadiazo-2-yl]-2,2′-bipyridyl (BP-OXD-Bpy), 3-(4-biphenyl)-4-phenyl-5-tert-butylphenyl-1,2,4-triazole (TAZ), 4-(naphthalen-1-yl)-3,5-diphenyl-4H-1,2,4-triazole (NTAZ), 2,9-bis(naphthalen-2-yl)-4,7-diphenyl-1,10-phenanthroline (NBphen), Tris(2,4,6-trimethyl-3-(pyridin-3-yl)phenyl)borane (3TPYMB), Phenyl-dipyrenylphosphine oxide (POPy2), 3,3′,5,5′-tetra[(m-pyridyl)-phen-3-yl]biphenyl (BP4mPy), 1,3,5-tri[(3-pyridyl)-phen-3-yl]benzene (TmPyPB), 1,3-bis[3,5-di(pyridin-3-yl)phenyl]benzene (BmPyPhB), Bis(10-hydroxybenzo[h]quinolinato)beryllium (Bepq2), bis(10-hydroxybenzo [h] quinolinato)-beryllium (Bebq2), Diphenylbis(4-(pyridin-3-yl)phenyl)silane (DPPS), 1,3,5-tri(p-pyrid-3-ylphenyl)benzene (TpPyPB), 3-(4,6-diphenyl-1,3,5-triazin-2-yl)-9-phenyl-9H-carbazole (DPTPCz), 2-(3-(3-(N,N-bis(4-(1,1-dimethylethyl)phenyl)-amino)phenyl)-phenyl)-4,6-diphenyl-1,3,5-triazine (tBu-TPA-m-TRZ), 9-(4,6-diphenyl-1,3,5-triazine-2-yl)-9′-phenyl-3,3′-bicarbazole (CzT), 2-(4-(3,6-dimethylcarbazol-9-yl)-phenoxy)-bis-4,6-biscarbazolyl-1,3,5-triazine (PCTrz), 3-(Carbazol-9-yl)-3′-(4,6-(dicarbazol-9-yl)-1,3,5-triazin-2-yl)-1,1′-biphenyl (BPTRZ), 3-(Carbazol-9-yl)-6,6′-dimethyl-3′-(4,6-(dicarbazol-9-yl)-1,3,5-triazin-2-yl)-1,1′-biphenyl (MBPTRZ), Balq (bis (8-hydroxy-2-methylquinolinonato)-aluminum biphenoxide), phenanthrolines based compounds (such as BCP (Bassocouplone) from UDC), 1,3-N, N-dicarbazole benzene (mCP), 4,4′-N, N-dicarbazolebiphenyl (CBP), 4,4′-bis (9-carbazolyl)-2,2′-dimethyl (CDBP), 1,4-bis 9H-carbazol-9-yl (DCB), trans-1,2-di-9-carbazolyl cyclobutane (DCz), 2,2-bis (4-carbazol-9-yl-phenyl) adamantane (Ad-Cz), 3,6-di (9-carbazolyl)-9-(2-ethylhexyl) carbazole (TCz1), 1,3,5-N, N′, N″ tridazolylmethyl-2,4,6-trimethyl (TCTEB), 2,2′-bis (4-carbazolylphenyl)-1,1′-biphenyl (4CzPBP), 2,6-bis (3-(9H-carbazol-9-yl) phenyl) pyridine (DCzPPy), bis(2-methylphenyl) diphenylsilane (UGH1), 1,4-bis (triphenylsilyl) benzene (UGH2), 1,3-bis (triphenylsilyl) benzene (UGH3), 4,4′-di (triphenyl) phenyl (BSB), tri phenyl (4-(9-phenyl 9H-fluoren-9-yl) phenyl) silane (TPSi-F), 2,6-bis (3-(9H-carbazol-9-yl) phenyl) pyridine (DPCzPSi), 4,4′-bis (diphenylphosphine oxide) phenyl (PO1), 2,7-bis (diphenylphosphine oxide)-9,9-dimethylfluorene (PO6), 2,7-dibromofluorene 9H (DBF), spirobifluoren-2-yl-diphenylphosphine oxide (SPPO1), N-(4-diphenylphosphoryl) carba (MPO12), 9,9′-(1-phenyl-1H-pyrrole-2,5-diyl) bis (9H-carbazole) (PPyCz2), 9′ phenyl 9′ H-9,2′7′, 9″ tert caba (27 PTCz), 9′ phenyl 9H-9, 3′, 6′, 9″t-carba (36PTCz), 8,8-bis (4-(9H-carbazol-9-yl) phenyl)-8-yl indolo [3,2,1-d] acridine (FPCC), 8,8-bis(4-(9H-carbazol-9-yl)phenyl)-8H-indolo[3,2,1-de]acridine (FPCA), 6,6-bis (4-(9H-carbazol-9-yl) phenyl)-6H pyrrolo [3,2,1-d] acridine (BCPPA), 6,6-bis (4-(1H-indol-1-yl) phenyl)-6H pyrrolo [3,2,1-d] acridine (BIPPA), 3,5-di (9H-carbazol-9-yl)-N,N-diphenyl aniline (DCDPA), 1,1-bis [4-[N, N′-diphenyl] cyclohexane (TAPC), 4,4′-(diphenylsilanediyl)bis(N,N-di-p-tolylaniline) (DTASi), 9-(9H-carbazol-9-yl) phenyl-3,6-bis (diphenyl)-9H-carbazole (CPBDC), 1,3-bis (3-(diphenyl)-9H-carbazol-9-yl) benzene (BCPCB), 2,2′-bis (3-tolyl aminophenyl)-1,1′-biphenyl (BTPD), tris [3-(3-pyridyl) mesityl] borane (3TPYMB), 4-(triphenylsilyl) phenyldiphenylphosphine oxide (TSPO1), dibenzofuran (PO14), dibenzothiophene (PO15), bis (4-(4, 5-diphenyl-4H-1,2,4-triazol-3-yl) phenyl)-dimethylsilane (SiTAZ), 8,8-bis(4-(1H-indol-1-yl)phenyl)-8H-indolo [3,2,1-de] acridine (BIPIA), 9-(3-(9H-carbazol-9-yl)phenyl)-9H-carbazol-3-yl)diphenylphosphine oxide (mCPPO1), [2-(diphenylphosphino)phenyl] ether oxide (DPEPO), 1,3-bis [4-(N, N-dimethylamino) phenyl-1,3,4-oxadiazoyl] benzene (OXD8), 2,7-bis(diphenyl)-9-[4-(N, N-diphenylamino) phenyl]-9-phenylfluorene (POAPF), bis-4-(N-carbazolyl) phenyl) diphenylphosphine oxide (BCPO), 4-diphenylphosphine oxide-4′-[3-(9H-carbazol-9-yl)-9H-carbazol-Tetraphenylsilane (DCSPO), (4-{1-[4-(diphenylphosphoryl) phenyl] cyclohexyl}phenyl) bis (4-methylphenyl) amine (POPCPA), {4-[diphenyl(4-pyridin-3-yl-phenyl)silyl]phenyl}diphenylamine (p-PySiTPA), {4-[[4-(diphenylphosphoryl)phenyl] (diphenyl)silyl]phenyl}diphenylamine (p-POSiTPA), [(diphenylsilanediyl)bis(4, 1-phenylene)]bis(diphenylphosphine) dioxide (SiDPO), 9-(8-(diphenyl)benzo [B, D] furan-2-yl)-9H-carbazole (DFCzPO), 2,8-di(9H-carbazol-9-yl)-benzo [B, D] thiophene (DBT1), 9-(8-(diphenyl)benzo [B, D] thiophen-2-yl)-9H-carbazole (DBT2), (diphenyl)benzo [B, D]thiophene-2,8-bis (DBT2), tetrakis (4-sulfonatophenyl) phthalocyanine (TSPC), (9-phenylo-9H-carbazole-2,5-diyl) bis (diphenylphosphine) oxide (PCPO25), 2,7-bis (diphenyl)-9-phenyl-9H-carbazole (PPO27), di (9H-carbazol-9-yl)-(phenyl) phosphine oxide (DCPPO1), 4-(N-A-carbolinyl)-4′,4″-(N-carbazolyl) triphenylamine (ADCTA), 4,4′-di (N-A-carbonyl)-4′-(N-carbazolyl) triphenylamine (DACTA), 4,4′,4″-(N-acarbonyl) triphenyl (TATA), 9-(4-(9H-pyrido [2,3-B] indol-9-yl) phenyl)-9H-3,9′-bicarbazole (pBCb2Cz), 9-(3′-(9H-carbazol-9-yl)-[1,1′-biphenyl]-3-yl)-9H-pyrido [2,3-B] indole (CzBPCb), 3,3-bis (9H pyrido [2,3-B]indol-9-yl)-1,1′biphenyl (CbBPCb), 9-(3″-(9H-carbazol-9-yl)-[1,1′:2′,1″-terphenyl]-3-yl)-α-carboline (CzOTCb), 3,3″-bis(α-carbolin-9-yl)-1,1′:2′,1″-terphenyl (CbOTCb), 9-(3-(Dibenzo-[B, D] furan-2-yl) phenyl)-α-carboline (PCb-DBF), 9-(3-(benzothiophen-2-yl) phenyl)-α-carboline (PCb-DBT), 9-(3-(9-phenylcarbazol-3-yl) phenyl)-α-carboline (PCb-PCz), [9-(3-(9H-carbazol-9-yl) phenyl)-9H-carbazole-3-carbonitrile] (mCPCN), 6-(2-(9H-carbazol-9-yl) phenyl)-9-ethyl-9H-carbazole-3-carbonitrile (o-CzCzCN), 6-(3,5-di(9H-carbazol-9-yl) phenyl)-9-ethyl-9H-carbazole-3-carbonitrile (mCPCzCN), 8-(3-(9H-carbazol-9-yl) phenyl) benzo [B, D] furan-2-carbonitrile (m-CzOCN), 8-(3-(9H-carbazol-9-yl) phenyl) benzo [B, D] thiophene-2-carbonitrile (m-CzSCN), benzo [B] thiophene (B2tCz), dibenzothiophen (DB2tCz), 6-(carbazol-9-yl)-benzo [2,3-b] pyridine (PCz-6BFP), 3-(3-(9H-carbazol-9-yl) phenyl) benzo [2,3-b] pyridine (PCz-BFP), 6-(carbazol-9-yl)-benzo [2,3-b]pyridine (Cz-6BFP), 3-(3-(9H-carbazol-9-yl) phenyl) benzo [4,5] thieno [2,3-b] pyridine (BTP1), 9-(3-(benzo [B, D] furan-2-yl) phenyl)-9H-carbazole (CzDBF), 3,5-bis (9-carbazolyl) tetraphenyl (SimCP), 3,5-di (9H-carbazol-9-yl) tetraphenyl (SimCP2), 9′-triphenylsilanol-9′H-[9,3′, 6′, 9″] tercarbazol (SitCz), 9,9′-(Oxybis([1,1′-biphenyl]-4′,3-diyl))bis(9H-carbazole) (CBBPE), 9-(5″-phenyl-[1,1′:2′,1″:3″,1′″-quaterphenyl]-3-yl)-9H-carbazole (CzTPPh), 9-(3″,5″-di(pyridin-3-yl)-[1,1:2′, 1″-terphenyl]-3-yl)-9H-carbazole (CzTPPy), 3,3″-di (9H-carbazol-9-yl)-1,1′2′, 1″-terphenyl (33DCTP), bis (2-(1H-pyrazol-1-yl) pyridin-3-olate) beryllium (BePyPy), Tris ((2-(pyrazol-1-yl) pyridin-3-yl) oxy) aluminum (Al(pypy)3), 2,7-bis (diphenylphosphoryl)-9,9′spiro [fluorene] (SPPO13), 5′,5-sulfonyl-1,1-di-[1,1′, 3′, 1″]-terphenyl (BTPS). These may be used independently or in combination of two or more.

The phosphorescent organic light emitting device according to one embodiment of the present disclosure includes two opposing electrodes and a phosphorescent light emission layer interposed between the electrodes, wherein the layer contains the above-described organic light-emitting compound and the host material.

Among the two electrodes, one is the anode and the other is the cathode. A hole transport layer, a blocking layer, a hole injection layer, and the like may be interposed between the anode and the phosphorescent light emission layer. An electron transport layer, a blocking layer, and an electron injection layer may be interposed between the cathode and the phosphorescent light emission layer.

The anode may be made of a conductive material having a high work function. The anode may be made of transparent and conductive indium tin oxide (ITO), indium zinc oxide (IZO), tin oxide (SnO₂), zinc oxide (ZnO), or the like.

The hole transport layer may be interposed between the anode and the phosphorescent light emission layer, and allow the holes injected from the anode to be transferred to the phosphorescent light emission layer. A blocking layer may be further formed between the phosphorescent light emission layer and the hole transport layer to prevent electrons from moving. Further, the hole injection layer may be further disposed between the anode and the hole transport layer.

The electron transport layer may be disposed between the phosphorescent light emission layer and the cathode. The blocking layer may be further formed between the phosphorescent light emission layer and the electron transport layer to prevent the movement of holes. Further, the electron injection layer may be further formed between the electron transporting layer and the cathode.

Developing the organic light-emitting compound with a phosphorescent characteristic at room temperature without containing a transition metal may allow triplet excitons to be used for luminescence, which otherwise may not be used and may be extinguished for luminescence in the conventional organic light-emitting compounds. As a result, the limited quantum efficiency of the organic light-emitting compound is improved. Further, the increase in the production cost and the instability of the molecular structure due to the introduction of the transition metal into the existing organometallic phosphorescent light emitting molecule may be eliminated. Further, conventional organic compounds exhibiting a phosphorescent characteristic at room temperature exhibit phosphorescent emission characteristics at room temperature only in a single crystal state thereof. Thus, the conventional organic compounds may not be easily applied to the organic electroluminescent device. However, the present organic compounds may be easily applied to the organic electroluminescent device.

Hereinafter, an organic light emitting device was fabricated to check the implementation of the light emission layer having a phosphorescent characteristic at room temperature. Results of evaluating the characteristics of the manufactured organic light emitting device will be described.

Preparation of Organic Light-Emitting Compound

Organic light-emitting compounds according to compounds 3-1 to 3-7 were prepared using the phenoselenazine synthesized according to the Reaction Formula 1, and according to Reaction Formula 2 to 8.

As a comparative example, Comparative Compound 1 was prepared according to a following Reaction Formula 9.

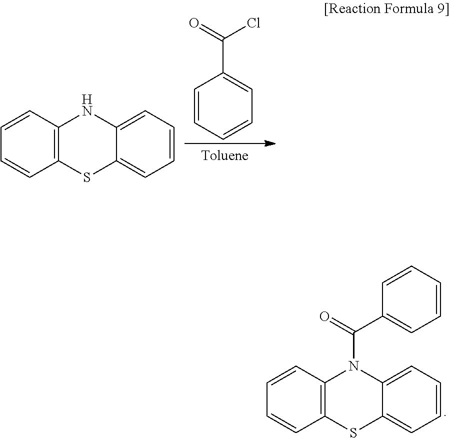

Evaluation of Characteristics

Compound Represented by Chemical Formula 3-1

The synthesized compound having the structure of the Chemical Formula 3-1 exhibited a room temperature-based phosphorescent characteristic in the crystal phase thereof. The luminescence spectrum of the compound having the structure of Chemical Formula 3-1 was observed with a delay time of 1 ms. As a result, a phosphorescent spectrum having a peak of 535 nm was obtained.

Compound with Structure of Chemical Formula 3-2

A synthesized compound having the structure of Chemical Formula 3-2 was doped into DPEPO at a volume ratio of 20. The luminescence spectrum thereof was observed with a delay time of 1 ms. As a result, a phosphorescent spectrum having a peak of 523.0 nm was obtained. An organic electroluminescent device using a room temperature-based phosphorescent material was fabricated. A structure of the fabricated device had ITO/PEDOT:PSS/TAPC/mCP/DPEPO:Compound/TSPO1/TPBi/LiF/Al. As a result, a room temperature-based phosphorescent device with an external quantum efficiency of 10.8% was obtained.

Compound with Structure of Chemical Formula 3-3

A synthesized compound having the structure of Chemical Formula 3-3 was doped into DPEPO at a volume ratio of 20. The luminescence spectrum thereof was observed with a delay time of 1 ms. As a result, a phosphorescent spectrum having a peak of 536.0 nm was obtained. An organic electroluminescent device using a room temperature-based phosphorescent material was fabricated. A structure of the fabricated device had ITO/PEDOT:PSS/TAPC/mCP/DPEPO:Compound/TSPO1/TPBi/LiF/Al. As a result, a room temperature-based phosphorescent device with an external quantum efficiency of 10.0% was obtained.

Compound with Structure of Chemical Formula 3-4

A synthesized compound having the structure of Chemical Formula 3-4 was doped into DPEPO at a volume ratio of 20. The luminescence spectrum thereof was observed with a delay time of 1 ms. As a result, a phosphorescent spectrum having a peak of 529.5 nm was obtained. An organic electroluminescent device using a room temperature-based phosphorescent material was fabricated. A structure of the fabricated device had ITO/PEDOT:PSS/TAPC/mCP/DPEPO:Compound/TSPO1/TPBi/LiF/Al. As a result, a room temperature-based phosphorescent device with an external quantum efficiency of 13.3% was obtained.

Compound with Structure of Chemical Formula 3-5

A synthesized compound having the structure of Chemical Formula 3-5 was doped into DPEPO at a volume ratio of 20. The luminescence spectrum thereof was observed with a delay time of 1 ms. As a result, a phosphorescent spectrum having a peak of 546.5 nm was obtained. An organic electroluminescent device using a room temperature-based phosphorescent material was fabricated. A structure of the fabricated device had ITO/PEDOT:PSS/TAPC/mCP/DPEPO:Compound/TSPO1/TPBi/LiF/Al. As a result, a room temperature-based phosphorescent device with an external quantum efficiency of 12.1% was obtained.

Compound with Structure of Chemical Formula 3-6

A synthesized compound having the structure of Chemical Formula 3-6 was doped into DPEPO at a volume ratio of 20. The luminescence spectrum thereof was observed with a delay time of 1 ms. As a result, a phosphorescent spectrum having a peak of 521.0 nm was obtained. An organic electroluminescent device using a room temperature-based phosphorescent material was fabricated. A structure of the fabricated device had ITO/PEDOT:PSS/TAPC/mCP/DPEPO:Compound/TSPO1/TPBi/LiF/Al. As a result, a room temperature-based phosphorescent device with an external quantum efficiency of 8.3% was obtained.

Compound with Structure of Chemical Formula 3-7

A synthesized compound having the structure of Chemical Formula 3-7 was doped into DPEPO at a volume ratio of 20. The luminescence spectrum thereof was observed with a delay time of 1 ms. As a result, a phosphorescent spectrum having a peak of 534.5 nm was obtained. An organic electroluminescent device using a room temperature-based phosphorescent material was fabricated. A structure of the fabricated device had ITO/PEDOT:PSS/TAPC/mCP/DPEPO:Compound/TSPO1/TPBi/LiF/Al. As a result, a room temperature-based phosphorescent device with an external quantum efficiency of 9.1% was obtained.

Comparative Compound (Compound Produced According to Reaction Formula 9)

The phosphorescent spectrum of the compound 2 as synthesized was observed with a delay time of 1 ms. The compound 2 did not have any phosphorescent characteristics in the crystal phase thereof. An organic electroluminescent device using the compound 2 was fabricated. A structure of the fabricated device had ITO/PEDOT:PSS/TAPC/mCP/DPEPO:Compound/TSPO1/TPBi/LiF/Al. The device did not exhibit phosphorescent emission characteristics.

While the present disclosure has been described with reference to preferred embodiments, those skilled in the art will appreciate that the present disclosure may be variously modified and changed without departing from the spirit and scope of the present disclosure set forth in the following claims.

What is claimed is:

1. An organic light-emitting compound having a phosphorescent characteristic at room temperature, the organic light-emitting compound including a compound represented by a following Chemical Formula 1: 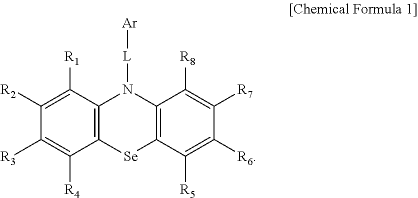
wherein, Ar represents an electron-donor unit or an electron-acceptor unit,
wherein L represents —(C₆H₄)ₙ—, where n is a natural number of 0 or 1 or greater,
wherein each of R₁ to R₈ independently represents a halogen atom, hydrogen, deuterium, an alkyl group having 1 to 60 carbon atoms, an alkenyl group having 2 to 60 carbon atoms, an alkynyl group having 2 to 60 carbon atoms, an aryl group having 6 to 60 carbon atoms, a heteroaryl group having 3 to 60 carbon atoms, an alkoxy group having 1 to 60 carbon atoms, an aryloxy group having 6 to 60 carbon atoms, an arylalkyl group having 7 to 60 carbon atoms, a heteroarylalkyl group having 3 to 60 carbon atoms, a cycloalkyl group having 3 to 60 carbon atoms, a heterocycloalkyl group having 1 to 60 carbon atoms, an alkylsilyl group having 3 to 60 carbon atoms, an arylsilyl group having 3 to 60 carbon atoms, or a heteroarylsilyl group having 1 to 60 carbon atoms,
wherein n of L is a natural number equal to or greater than 1, and in each of L and Ar, each of at least one hydrogen is independently substitutable with a halogen element, an alkyl group having 1 to 60 carbon atoms, an alkenyl group having 2 to 60 carbon atoms, an alkynyl group having 2 to 60 carbon atoms, an aryl group having 6 to 60 carbon atoms, a heteroaryl group having 3 to 60 carbon atoms, an alkoxy group having 1 to 60 carbon atoms, an aryloxy group having 6 to 60 carbon atoms, an arylalkyl group having 7 to 60 carbon atoms, a heteroarylalkyl group having 3 to 60 carbon atoms, a cycloalkyl group having 3 to 60 carbon atoms, a heterocycloalkyl group having 1 to 60 carbon atoms, an alkylsilyl group having 3 to 60 carbon atoms, an arylsilyl group having 3 to 60 carbon atoms or a heteroarylsilyl group having 1 to 60 carbon atoms.

2. The organic light-emitting compound of claim 1, wherein the electron-donor unit includes a functional group derived from a compound represented by each of following Chemical Formulas (1-1) to (1-36):

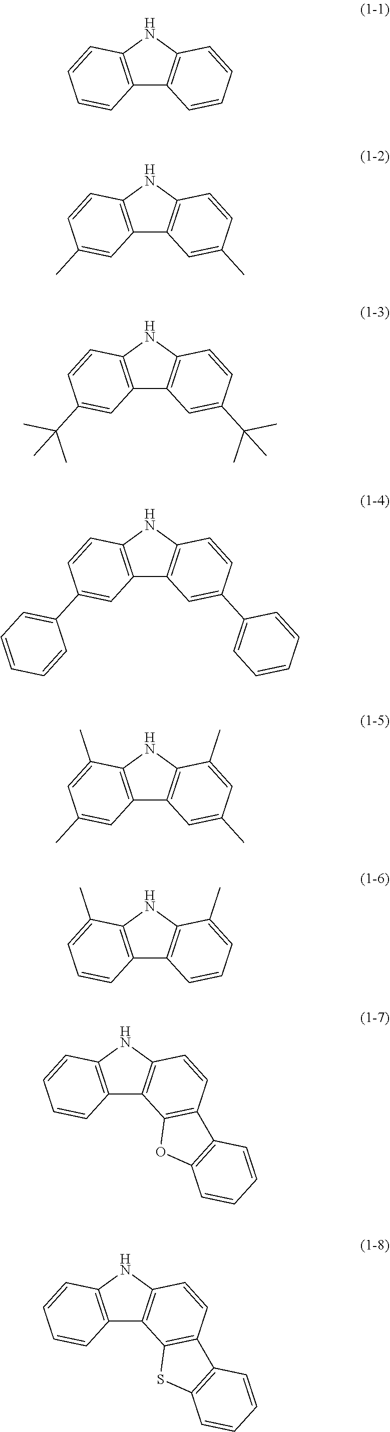

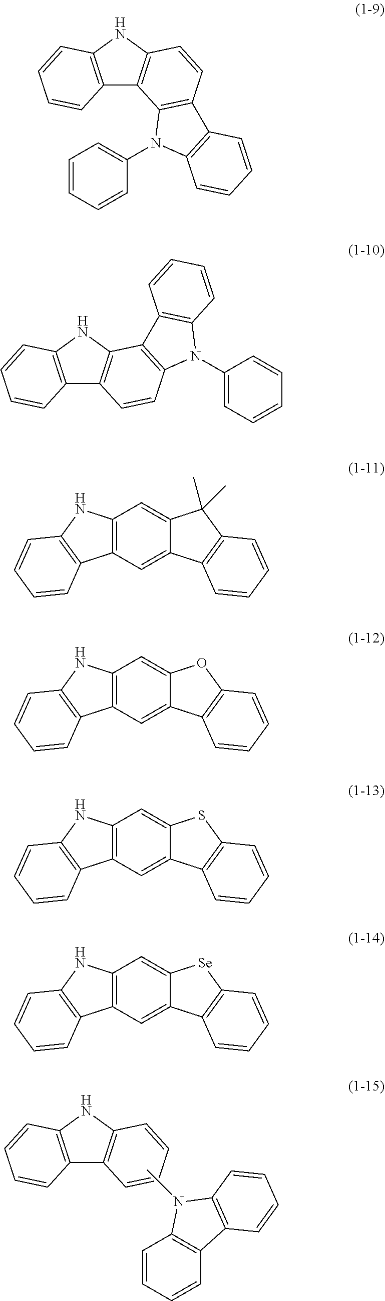

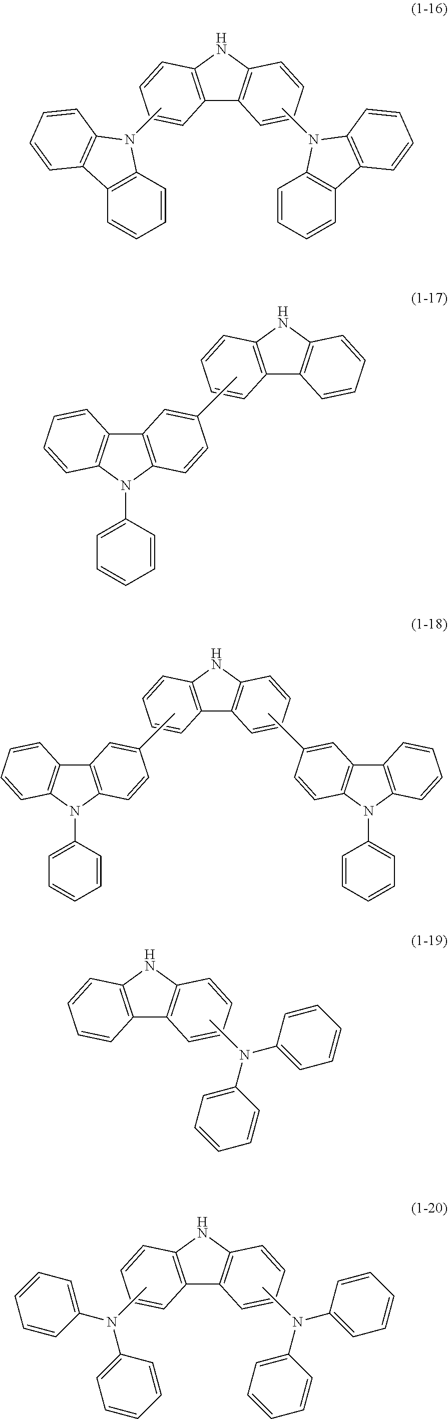

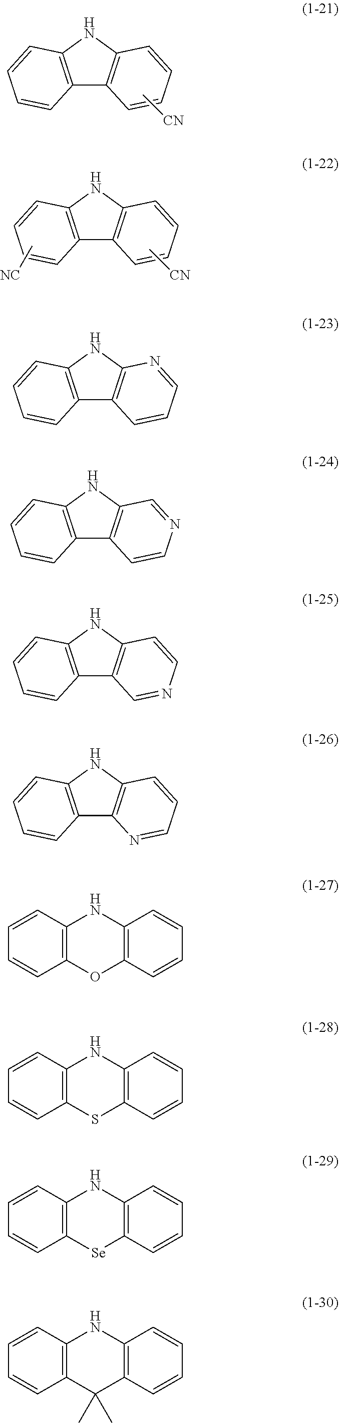

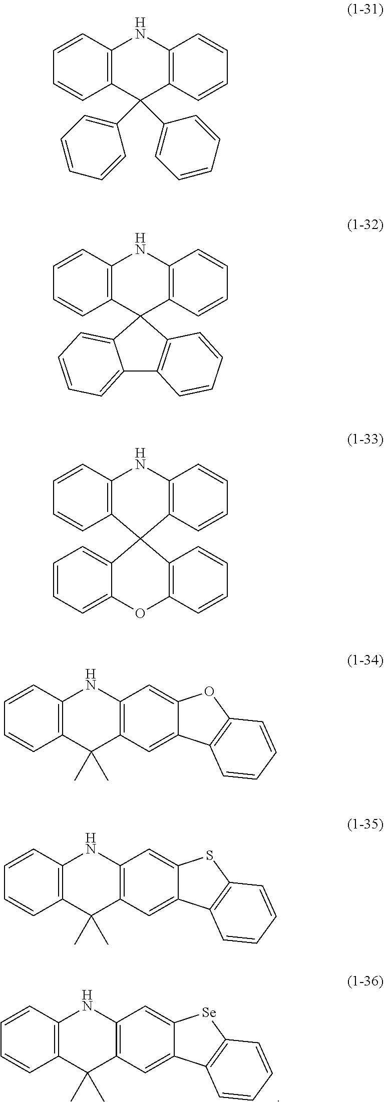

3. The organic light-emitting compound of claim 1, wherein the electron-acceptor unit includes a functional group represented by each of following Chemical Formulas (2-1) to (2-13): 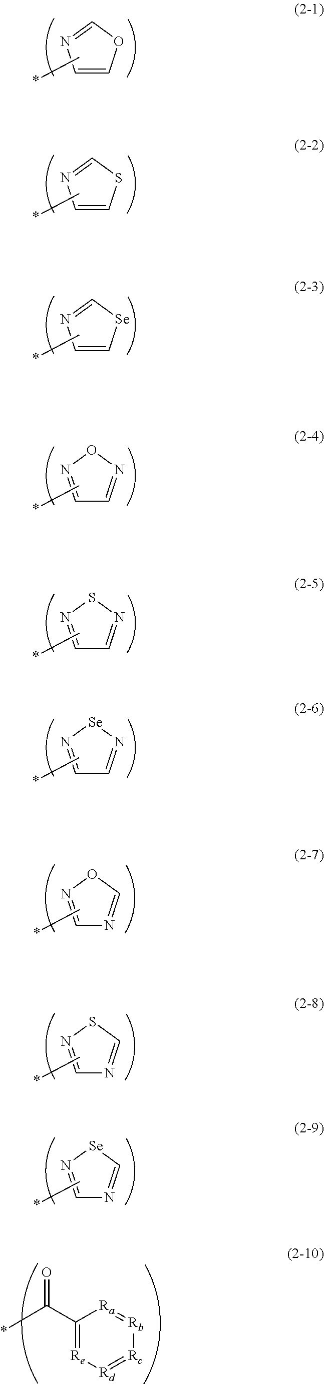 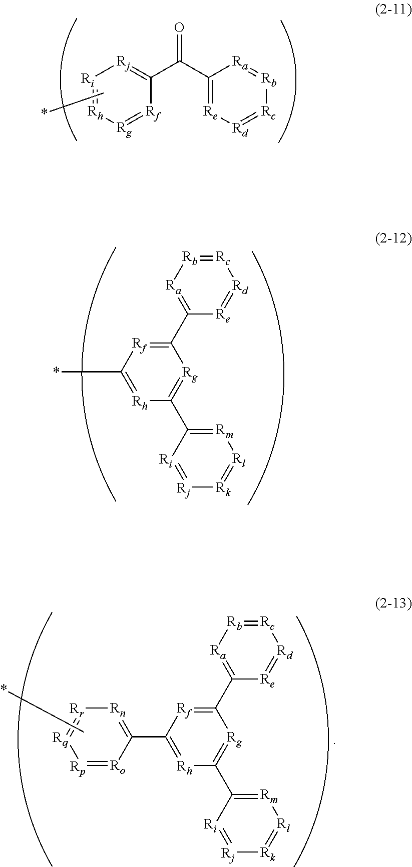
wherein each of Rₐ to Rₑ of Chemical Formula (2-10), each of Rₐ to Rⱼ of Chemical Formula (2-11), each of Rₐ to Rₘ of Chemical Formula (2-12), and each of Rₐ to Rᵣ of Chemical Formula (2-13) independently represents C, S, O, N or Se.

4. The organic light-emitting compound of claim 1, wherein the compound represented by the Chemical Formula 1 includes a compound represented by a following Chemical Formula 3-1:

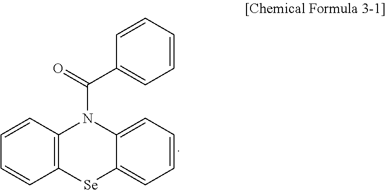 [SMILES: O=C(c1ccccc1)N1c2ccccc2[Se]c2ccccc21]

5. The organic light-emitting compound of claim 1, wherein the compound represented by the Chemical Formula 1 includes at least one of compounds represented by a following Chemical Formula 3-2 and a following Chemical Formula 3-3:

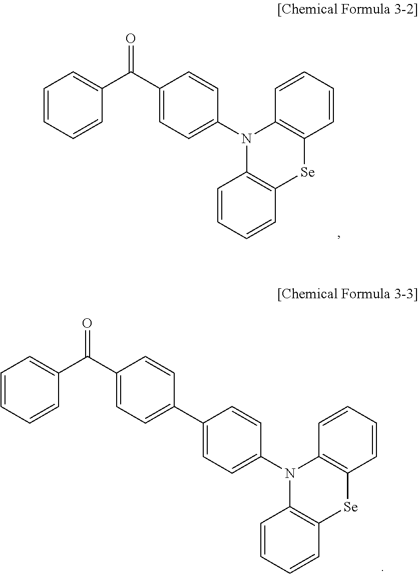 [SMILES: O=C(c1ccccc1)c1ccc(N2c3ccccc3[Se]c3ccccc32)cc1 ; "," ; O=C(c1ccccc1)c1ccc(-c2ccc(N3c4ccccc4[Se]c4ccccc43)cc2)cc1 ; "."]

6. The organic light-emitting compound of claim 1, wherein the compound represented by the Chemical Formula 1 includes at least one of compounds represented by following Chemical Formulas 3-4 to 3-7:

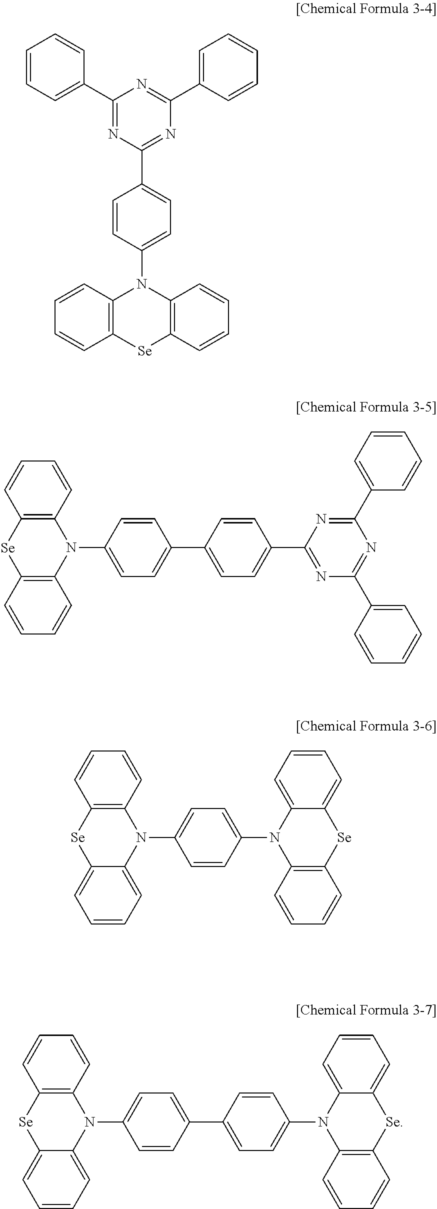

7. An organic light emitting device comprising:
an anode and an cathode facing away each other; and
a phosphorescent light emission layer disposed between the anode and the cathode,
wherein the phosphorescent light emission layer contains a host compound and a dopant, wherein the dopant includes the organic light-emitting compound of claim 1.

8. An organic light emitting device comprising:
an anode and an cathode facing away each other; and
a phosphorescent light emission layer disposed between the anode and the cathode,
wherein the phosphorescent light emission layer contains a host compound and a dopant, wherein the dopant includes the organic light-emitting compound of claim 2.

9. An organic light emitting device comprising:
an anode and an cathode facing away each other; and
a phosphorescent light emission layer disposed between the anode and the cathode,
wherein the phosphorescent light emission layer contains a host compound and a dopant, wherein the dopant includes the organic light-emitting compound of claim 3.

10. An organic light emitting device comprising:
an anode and an cathode facing away each other; and
a phosphorescent light emission layer disposed between the anode and the cathode,
wherein the phosphorescent light emission layer contains a host compound and a dopant, wherein the dopant includes the organic light-emitting compound of claim 4.

11. An organic light emitting device comprising:
an anode and an cathode facing away each other; and
a phosphorescent light emission layer disposed between the anode and the cathode,
wherein the phosphorescent light emission layer contains a host compound and a dopant, wherein the dopant includes the organic light-emitting compound of claim 5.

12. An organic light emitting device comprising:
an anode and an cathode facing away each other; and
a phosphorescent light emission layer disposed between the anode and the cathode,
wherein the phosphorescent light emission layer contains a host compound and a dopant, wherein the dopant includes the organic light-emitting compound of claim 6.
